(19) United States
(12) Patent Application Publication
(10) Pub. No.: US 2012/0199873 A1
(43) Pub. Date: Aug. 9, 2012

(54) METAL SUBSTRATE FOR LIGHT-EMITTING DIODE, LIGHT-EMITTING DIODE, AND METHOD FOR MANUFACTURING LIGHT-EMITTING DIODE

(75) Inventors: Atsushi Matsumura, Chichibu-shi (JP); Ryouichi Takeuchi, Chichibu-shi (JP)

(73) Assignee: SHOWA DENKO K.K., Minato-ku, Tokyo (JP)

(21) Appl. No.: 13/500,479

(22) PCT Filed: Sep. 30, 2010
(86) PCT No.: PCT/JP2010/067069

§ 371 Date: Apr. 5, 2012

(30) Foreign Application Priority Data
Oct. 7, 2009 (JP) 2009-233748

(51) Int. Cl. H01L 33/30; H01L 33/48

(52) U.S. Cl. 257/103; 257/79; 438/46; 257/E33.023

(57) ABSTRACT

The object of the present invention is to provide a metal substrate for a light-emitting diode having excellent chemical resistance, a light-emitting diode, and a method for manufacturing the light-emitting diode, and the present invention provides a metal substrate for a light-emitting diode including a metal substrate, a compound semiconductor layer having a light-emitting portion, which is joined over the metal substrate via a junction layer, wherein the metal substrate for a light-emitting diode includes a metal plate and a metal protective film which covers at least an upper surface and a lower surface of the metal plate.

### TECHNICAL FIELD

The present invention relates to a metal substrate for a light-emitting diode, a light-emitting diode, and a method for manufacturing the light-emitting diode.

Priority is claimed on Japanese Patent Application No. 2009-233748 filed Oct. 7, 2009, the contents of which are incorporated herein by reference.

### BACKGROUND ART

As a high output light-emitting diode (LED) which emits red light or infrared light, a compound semiconductor LED including a light-emitting layer containing aluminum gallium arsenide (compositional formula: AlₓGa₁₋ₓAs; 0≦X≦1) is known.

On the other hand, as a light intensity light-emitting diode which emits red, orange, yellow or yellowish green visible light, a compound semiconductor LED including a light-emitting layer containing aluminium gallium indium phosphide (compositional formula:(AlₓGa₁₋ₓ)_{y}In_{1-Y}P; 0≦X≦1, 0<Y≦1) is also known.

In general, these LEDs are formed on a substrate, which is optically opaque to light emitted from the light-emitting layer, and is made of gallium arsenide (GaAs), etc. having a not very high mechanical strength.

Therefore, recently, in order to obtain a LED having higher light intensity, or improve mechanical strength and heat dissipation of elements, a technique has been disclosed in which, after removing the opaque substrate to emitted light, a support layer (substrate), which transmits or reflects emitted light, and is formed of a material having excellent mechanical strength and heat dissipation, is joined again to produce a composite type LED (For example, Patent Documents 1 to 7).

### CITATION LIST

### Patent Documents

[Patent Document 1] Japanese Unexamined Patent Application, First Publication No. 2001-339100
[Patent Document 2] Japanese Unexamined Patent Application, First Publication No. Hei 6-302857
[Patent Document 3] Japanese Unexamined Patent Application, First Publication No. 2002-246640
[Patent Document 4] Japanese Patent No. 2588849
[Patent Document 5] Japanese Unexamined Patent Application, First Publication No. 2001-57441
[Patent Document 6] Japanese Unexamined Patent Application, First Publication No. 2007-81010
[Patent Document 7] Japanese Unexamined. Patent Application, First Publication No. 2006-32952

### SUMMARY OF INVENTION

### Technical Problem

As explained above, since the development of a technique for joining the substrate, the degree of freedom of the substrate which can be used as a support layer has increased, and many metal substrates having a great advantage to cost, mechanical strength, or heat dissipation have been suggested.

However, the metal substrate has problems in that quality is degraded by reaction and corrosion with chemical agents used in manufacturing processes, compared with semiconductor substrates, ceramics substrates, etc. Specifically, the metal substrate is dissolved, discolored, or corroded in an alkali or acid treatment, and this causes inferior characteristics or lower yield, which are problems.

In particular, in order to remove the gallium arsenide substrate which is used to grow the semiconductor, a step in which the gallium arsenide substrate is completely dissolved by immersing into alkali or acid for a long period of time is generally used. However, the metal substrate cannot endure the chemical agent treatment for a long period of time.

In consideration of the above-described problems, it is an object of the present invention to provide a metal substrate for a light-emitting diode having a new structure and excellent chemical resistance which can endure chemical agents in the step of removing the substrate.

In addition, it is another object of the present invention to provide a light emitting diode having stable properties by using the metal substrate.

Furthermore, it is another object of the present invention to provide a method for manufacturing a light-emitting diode having stable properties with high yield.

### Solution to Problem

In order to attain the foregoing objects, the present invention provides the following inventions (1) to (9).

(1) A metal substrate for a light-emitting diode including a metal substrate, and a compound semiconductor layer having a light-emitting portion, which is joined over the metal substrate via a junction layer,

wherein the metal substrate for a light-emitting diode includes a metal plate and a metal protective film which covers at least an upper surface and a lower surface of the metal plate.

(2) The metal substrate for a light-emitting diode according to (1), wherein the metal protective layer further covers side surfaces of the metal plate.
(3) The metal substrate for a light-emitting diode according to (1) or (2), wherein the metal plate has a thermal conductivity of 130 W/m·K or more, and a thermal expansion coefficient which is denoted by a thermal expansion coefficient of the light-emitting portion±1.5 ppm/K.
(4) The metal substrate for a light-emitting diode according to any one of (1) to (3), wherein the metal plate includes at least one of a copper thin plate, a molybdenum thin plate, and a tungsten thin plate.
(5) The metal substrate for a light-emitting diode according to (4), wherein the metal plate has a structure in which a copper plate and molybdenum plate are laminated.
(6) The metal substrate for a light-emitting diode according to any one of (1) to (5), wherein the metal protective film includes at least one of nickel, chromium, platinum, and gold.
(7) A light-emitting diode including a metal substrate according to any one of (1) to (6), and a compound semiconductor layer having a light-emitting portion, which is joined over the metal substrate via a junction layer, wherein the light-emitting portion includes an AlGaInP layer or an AlGaAs layer.
(8) A method for manufacturing a light-emitting diode including:

a first step of forming a metal protective layer on the entire surfaces of a metal plate to produce a metal substrate for a light-emitting diode;

a second step of forming a compound semiconductor layer including a light-emitting portion on a semiconductor substrate;

a third step of forming a junction layer on the compound semiconductor layer;

a fourth step of joining the semiconductor substrate, on which the compound semiconductor layer is formed, and the metal substrate via the junction layer; and

a fifth step of removing the semiconductor substrate using an etchant.

(9) The method for manufacturing a light-emitting diode according to (8), wherein the first step includes a step of forming the metal plate by thermal-compression bonding plural metal thin plates, and a step of forming the metal protective film on the entire surfaces of the metal plate by plating.

### Advantageous Effects of Invention

According to the present invention, it is possible to provide a metal substrate for a light-emitting diode having a new structure with excellent heat dissipation ability and chemical resistance which can endure a chemical treatment in a substrate removing step. In addition, it is also possible to provide a light-emitting diode having stable properties. Furthermore, it is also possible to provide a method for manufacturing a light-emitting diode having stable properties with high yield.

### BRIEF DESCRIPTION OF DRAWINGS

FIG. 1A is a planar view showing one embodiment of a metal substrate for a light-emitting diode and a light-emitting diode which is joined to the metal substrate according to the present invention.

FIG. 1B is a sectional view showing one embodiment of a metal substrate for a light-emitting diode and a light-emitting diode which is joined to the metal substrate according to the present invention.

FIG. 2 is a sectional view showing one embodiment of a light-emitting diode according to the present invention.

FIG. 3 is a sectional schematic view showing one embodiment of one step of a method for manufacturing a light-emitting diode according to the present invention.

FIG. 4A is a planar view showing a conventional metal substrate for a light-emitting diode and a conventional light-emitting diode which is joined to the metal substrate.

FIG. 4B is a sectional view showing one embodiment of a conventional metal substrate for a light-emitting diode and a conventional light-emitting diode which is joined to the metal substrate.

### DESCRIPTION OF EMBODIMENTS

A metal substrate for a light-emitting diode, a light-emitting diode, and a method for manufacturing the light-emitting diode are explained below in detail referring to the figures.

Moreover, the figures used in the following embodiments are for explaining the construction of the embodiments according to the present invention. For convenience, the characteristic part may be enlarged. The proportion of each element shown in the figures may be different from the actual proportion. The detailed explanation of an element is omitted by attaching the same reference number to the same element.

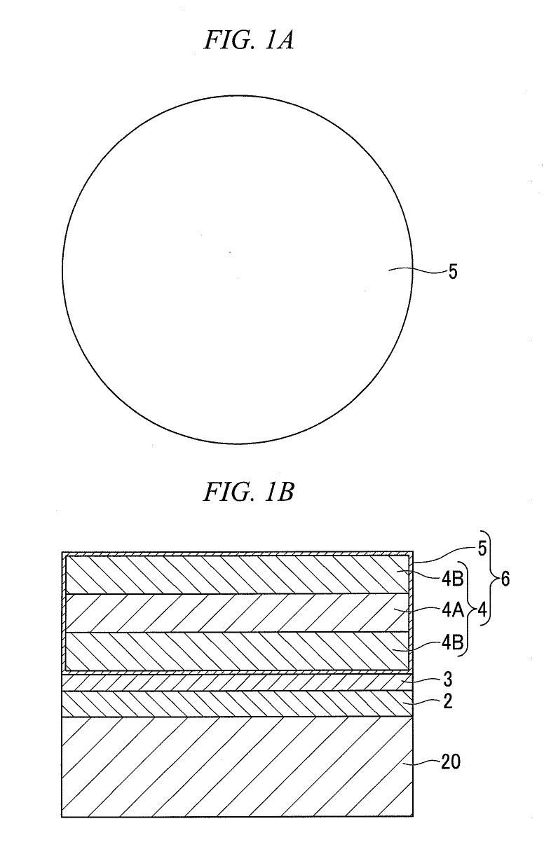

FIGS. 1A and 1B show conditions of the laminate to be a light-emitting diode in a fourth step of the method for manufacturing a light-emitting diode according to the present invention. The method for manufacturing a light-emitting diode according to the present invention will be explained in detail below.

In FIGS. 1B, a metal substrate 6 for a light-emitting diode according to the present invention and a compound semiconductor layer 2 including a light-emitting portion formed on a grown substrate (semiconductor substrate) are joined via a junction layer 3.

[Metal Substrate for Light-Emitting Diode]

As shown in FIG. 1B, the metal substrate 6 according to this embodiment includes a metal plate 4 and a metal protective film 5 which covers the entire surfaces, that is, the upper surface, the lower surface and the side surfaces of the metal plate 4.

Moreover, the metal protective layer 5 may cover only the upper and lower surfaces of the metal plate 4, not side surfaces.

It is preferable that the thermal conductivity of the metal plate 4 be 130 W/m·K or more, and the thermal expansion coefficient be denoted by a thermal expansion coefficient of the light-emitting portion±1.5 ppm/K.

Specifically, the metal plate 4 may be formed of a material having a high thermal conductivity, such as copper, silver, and gold, or metal having substantially the same thermal expansion coefficient as that of the light-emitting portion 7, such as molybdenum, and tungsten. In addition, the metal plate 4 may also be made of plural metal thin plates. The metal plate 4 preferably includes at least one of a copper thin plate, a molybdenum thin plate, and a tungsten thin plate. In particular, as shown in FIG. 1B, the metal plate 4 is preferably a laminate obtained by laminating and thermal-compression bonding a copper thin plate 4B/a molybdenum thin plate 4A/a copper thin plate 4B. It is possible to make the thermal expansion coefficient of the metal plate 6 substantially equal to the thermal expansion coefficient of the light-emitting portion 7 by using such a structure.

The metal protective film 5 which covers at least the upper and lower surfaces of the metal plate 4 can be made of a well-known material such as nickel, chromium, platinum and gold.

Among these materials, the metal protective film 5 is preferably a layer combining nickel having excellent adhesion and gold having high chemical resistance. It is preferable that the metal protective film 5 be produced by forming an under layer made of nickel, and then coating the under layer with gold or platinum having high chemical resistance. The metal protective film 5 can be formed by plating the entire surfaces of the metal plate 4 with nickel/gold.

The thickness of the metal protective film 5 is not particularly limited. However, when the balance between durability and cost is concerned, the thickness of the metal protective film 5 is preferably in a range of 0.2 to 5 pa, more preferably in a range of 0.5 to 3 μm. The thickness of the layer made of gold, which is expensive, is preferably 1 μm or less.

The metal substrate 6 having such a structure has a problem in that when the metal substrate 6 is thin, deformation is caused by insufficient strength, and when it is thick, high technique is required in a step of cutting the metal substrate 6 into chips. Therefore, it depends on the kinds of material constituting the metal substrate 6, but the thickness of the metal substrate 6 is preferably in a range of 50 to 200 μm, and more preferably in a range of 80 to 150

[Light-Emitting Diode]

Next, the light-emitting diode will be explained.

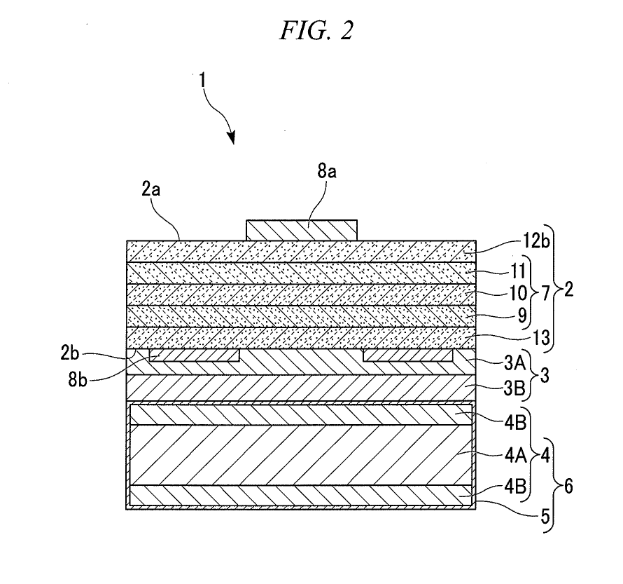

As shown in FIG. 2, the light-emitting diode (LED) according to this embodiment includes the metal substrate 6 according to the present invention and the compound semiconductor layer 2 which has the light-emitting portion 7 and is joined over the metal substrate 6 via the junction layer 3.

The compound semiconductor layer 2 is not particularly limited as long as it has a pn-junction type light-emitting portion 7.

The light-emitting portion 7 is made of a material which grows on a semiconductor substrate, such as a GaAs substrate. In general, the light-emitting portion 7 is a laminate of a compound semiconductor in which a lower clad layer 9, a light-emitting layer 10, and an upper clad layer 11 are laminated in this order.

As the light-emitting portion 7, for example, a compound semiconductor layer including the light-emitting layer 10 containing (AlₓGa_{1-X})_{Y}In_{1-Y}P (0≦X≦1,0<Y≦1) which is a light source of red, yellow, and/or yellowish green light can be used. In addition, a compound semiconductor layer including the light-emitting layer 10 containing Al_{X}Ga_{1-X}As (0≦X≦1) which is a light source of red and inferred light can also be used. Any other well-known structure can also be used.

The junction layer 3 is positioned between the compound semiconductor layer 2 and the metal substrate 6, and strongly joints (attaches) the compound semiconductor layer 2 to the metal substrate 6. The junction layer 3 may be a single layer or a plural layer. However, when the combination with the material constituting the metal protective layer 5 is concerned, the junction layer 3 is preferably made of the same material as that constituting the junction surface of the metal substrate 6 which joints to the junction layer 3, that is, the material constituting the metal protective layer 5. For example, when the metal protective layer 5 is made of gold, the junction layer 3 which functions as the junction surface to the metal protective layer 5 is most preferably made of gold.

In this embodiment, the junction layer 3 includes a first metal film 3A formed in the side of the compound semiconductor layer 2 and a second metal film 3B which is formed in the side of the metal substrate 6. The second metal film 3B is made of the same material as that constituting the metal protective film 5.

In addition, the junction layer 3 has a structure having a high reflectivity due to high light intensity in this embodiment. Due to this, the junction layer 3 reflects the incident light from the sides of the compound semiconductor layer 2 and the metal substrate 6.

[Method for Manufacturing Light-Emitting Diode]

Next, the method for manufacturing the light-emitting diode is explained by dividing into the first to fifth step below.

[Step of Manufacturing Metal Substrate (First Step)]

The metal substrate 6 for a light-emitting diode is prepared as shown below.

First, the metal plate 4 constituting the metal substrate 6 for a light-emitting diode is prepared.

The metal plate 4 shown in FIG. 2 is obtained by laminating and thermal-compression bonding three thin plates, that is, a copper thin plate 4B, a molybdenum thin plate 4A and a copper thin plate 4B such that the thermal expansion coefficient of the metal plate 4 is substantially equal to the thermal expansion coefficient of the light-emitting portion 7.

Next, the metal protective film 5 covering the entire surfaces of the metal plate 4 is prepared.

The metal protective film 5 can be prepared by a well-known method. However, since a plating method can form the entire surfaces including the side surfaces of the metal plate 4, the plating method is preferably used.

Any well-known technique and chemical agents can be used in plating. Among plating methods, an electroless plating is preferably used because it does not need an electrode and is simple.

Any well-known plating materials, such as copper, silver, nickel, chromium, platinum, and gold can be used without limitation. However, a layer combining nickel, which has high adhesion, and gold, which has high chemical resistance, is most preferable.

For example, when the electroless plating is used, the metal protective film 5 including a nickel film and a gold film can be prepared by plating the upper, side, and lower surfaces of the metal plate 6 with nickel, and then plating with gold.

The thickness of the plating is not particularly limited. However, when the balance between durability and cost is concerned, the thickness of the metal protective film 5 is preferably in a range of 0.2 to 5 μm, more preferably in a range of 0.5 to 3 μm. The thickness of the layer made of gold, which is expensive, is preferably 1 μm or less.

Moreover, the metal protective layer 5 only has to cover the entire surfaces of the metal plate 4 in the subsequent removing step of a semiconductor substrate. In the steps after the removing step of a semiconductor substrate, a part of the metal protective film 5 may be removed. In addition, the metal protective film 5 need not cover the entire surfaces of the metal plate 4 in the final light-emitting diode.

[Step of Manufacturing Compound Semiconductor Layer (Second Step)]

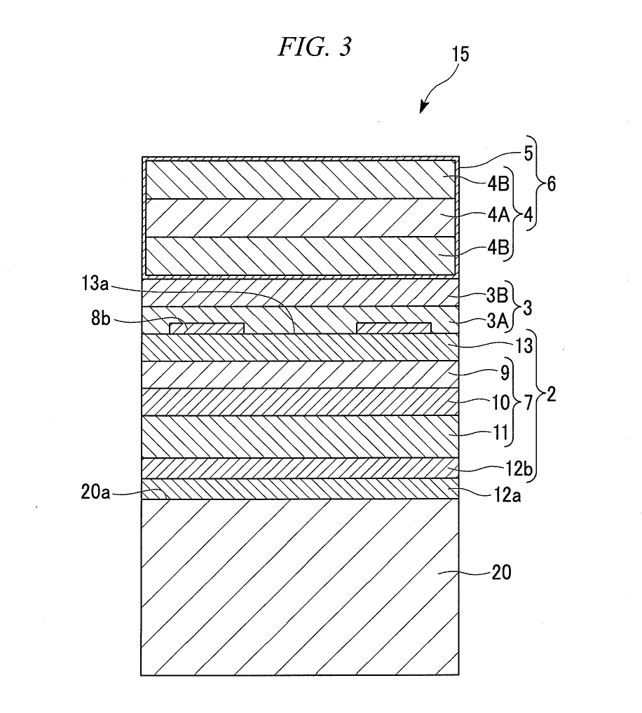

As shown in FIG. 3, the semiconductor layer 2 is formed on one surface 20a of the semiconductor substrate 20 by growing plural epitaxial layers.

The semiconductor substrate 20 is a substrate for forming the compound semiconductor layer 2. For example, the semiconductor substrate 20 is a Si-doped n-type GaAs single crystal substrate.

A buffer layer 12a containing Si-doped n-type GaAs is formed on one surface 20a of the semiconductor substrate 20. After that, a contact layer 12b containing Si-doped n-type AlGaInP is formed on the buffer layer 12a. Then, a clad layer 11 containing Si-doped n-type AlGaInP is formed on the contact layer 12b. A light-emitting layer 10 having a lamination structure including ten pairs of undoped AlGaInP/AlGaInP is formed on the clad layer 11.

Then, a clad layer 9 containing Mg-doped p-type AlGaInP is formed on the light-emitting layer 10. After that, a Mg-doped p-type GaP layer 13 is formed on the clad layer 9.

Then, a second electrode (ohmic electrode) 8b is formed on surface 13a of the Mg-doped p-type GaP layer 13, which is opposite to the surface 20a of the semiconductor layer 2.

[Step of Manufacturing Junction Layer (Third Step)]

Then, a junction layer 3 (3A) is formed so as to cover the surface 13a of the p-type GaP layer 13, which is opposite to the semiconductor substrate 20, and the second electrode 8b.

Any well-known technique can be used to prepare the junction layer 3 (3A). For example, eutectoid metal, metal substances such as solder, organic adhesive, or direct junction technique can be used.

[Step of Joining Metal Substrate (Fourth Step)]

The semiconductor substrate 20 including the junction layer 3 and the compound semiconductor layer 2 and the metal substrate 6 prepared in the step of manufacturing the metal substrate are introduced into a compression device, and they are positioned such that the junction surface of the junction layer 3 faces and is placed on the junction surface of the metal substrate 6.

Then, after ventilating the compression device, the semiconductor substrate 20 including the junction layer 3 and the compound semiconductor layer 2 and the metal substrate 6 are pressed while heating, and a junction structure 15 is prepared.

[Step of Removing Semiconductor Substrate (Fifth Step)]

Then, the semiconductor substrate 20 and the buffer layer 12a are selectively dissolved and removed from the junction structure 15 using an etchant containing ammonia and hydrogen peroxide.

Copper is dissolved in the etchant. However, since the metal plate 4 of which the entire surfaces are covered with the metal protective film 5 is a nickel/gold film, the metal plate 4 is not dissolved.

The compound semiconductor layer 2 having the light-emitting portion 7 can be produced by these steps.

[Step of Manufacturing First Electrode]

Next, a first electrode 8a is formed on a surface 2a of the compound semiconductor layer 2 which is opposite to the metal substrate 6.

[Step of Separating]

After removing the semiconductor layer which is positioned on an area to be cut, the structure including the metal substrate 6 obtained by these steps is cut at 350 μm intervals. Thereby, the light-emitting diode 1 is prepared.

In the obtained light-emitting diode, the metal protective layer 5 is formed on the upper and lower surfaces of the metal substrate 6, not on the side surfaces.

[Step of Manufacturing Metal Protective Film on Side Surfaces of Light-Emitting Diode]

The light-emitting diode can also be manufactured by subjecting the side surfaces and the lower surface of the cut metal substrate 6 to a nickel/gold plating under the same conditions as those in a step of manufacturing the metal protective film 5, and removing the resin protective film. The light-emitting diode obtained in this way has high chemical resistance, which is preferable.

### EXAMPLES

The present embodiment will be described in more detail below referring the following Examples, although the present embodiment is in no way limited by the following Examples.

[Preparation of Metal Substrate]

A Mo foil having a thickness of 25 μm was sandwiched with two copper foils having a thickness of 30 μm, and thermal compression bonded to produce a metal plate 4 having a thickness of 85 μm. The shape of the metal plate 4 is a circle having a diameter of 76 mm.

Then, the upper and lower surfaces of the metal plate 4 were polished to make the upper surfaces glossy. Then, the metal plate 4 was washed with an organic solvent to remove impurities.

The thermal expansion coefficient and the thermal conductivity of the metal plate 4 were 6.1 ppm/K and 250 W/m·K, respectively.

The metal plate 4 was plated with Ni such that the thickness of the Ni layer was about 2 μm, and then Au such that the thickness of the Au layer was 0.5 p.m. Thereby, the metal protective film 5 having two uniformly plated layers was formed on the upper, sides, and lower surfaces of the metal plate 4.

[Formation of Light-Emitting Portion]

A GaAs single crystal substrate 20 which has a diameter of 76 mm, a thickness of 450 μm, and the main surface of (100) 15° off was prepared. After washing the surfaces of the GaAs single crystal substrate 20, the GaAs single crystal substrate 20 was set in a MOCVD device.

A GaAs buffer layer 12 was grown on the GaAs single crystal substrate 20 such that the thickness was 0.2 μm. Then, a contact layer 12b, which contains Si-doped n-type (Al_{0.5}Ga_{0.5})_{0.5}In_{0.5}P, and has a carrier concentration of 2×10¹⁸ cm⁻³, and a thickness of 1.5 μm, was formed.

Then, a clad layer 11 which contains Si-doped n-type (Al_{0.7}Ga_{0.3})_{0.5}In_{0.5}P, and has a carrier concentration of 8×10¹⁷ cm⁻³, and a thickness of 1 μm, was formed.

After that, a light-emitting layer 10, which has ten pairs of undoped (Al_{0.2}Ga_{0.8})_{0.5}In_{0.5}P/(Al_{0.7}Ga_{0.3})_{0.5}In_{0.5}P, was formed.

Then, a clad layer, which contains Mg-doped p-type (Al_{0.7}Ga_{0.3})_{0.5}In_{0.5}P, and has a carrier concentration of 2×10¹⁷ cm⁻³, and a thickness of 1 μm, was formed. Then, a GaP layer 13, which contains Mg-doped p-type GaP, and has a carrier concentration of 3×10¹⁸ cm⁻³, and a thickness of 3 μm, was formed.

In addition, an ohmic electrode 8b was formed on the surface of the obtained p-type GaP layer 13. Furthermore, an AuGe eutectic metal having a thickness of 1.5 μm was deposited by a deposition method as a junction layer 3.

Then, the metal substrate 6 was attached to the junction layer 3, and they were heated to 380° C. and pressed to produce a junction structure 15 in an attaching device.

[Remove of Semiconductor Substrate]

The obtained junction structure 15 was immersed in a mixture solution containing ammonia and hydrogen peroxide until the GaAs substrate 20 and the GaAs buffer layer 12a were completely dissolved.

[Junction Percentage]

After dissolving and removing the GaAs substrate 20 and the GaAs buffer layer 12a, the junction percentage was measured. As a result, the area of 97% relative to the theoretical area (S) was good.

Here, the theoretical area (S) means an effective area before junction, and the effective area is obtained by subtracting the area of the orientation flat and the beveling around the edges from the entire area of a wafer having a circle shape. When a wafer having a diameter of 76 mm is used, S is 43 cm².

In addition, the junction percentage means a percentage of the area (X) joined relative to the theoretical area (S), and is represented by (X/S)×100 (%).

Moreover, the area (X) joined can be measured by an area-measuring machine after removing the joined part.

### Comparative Example

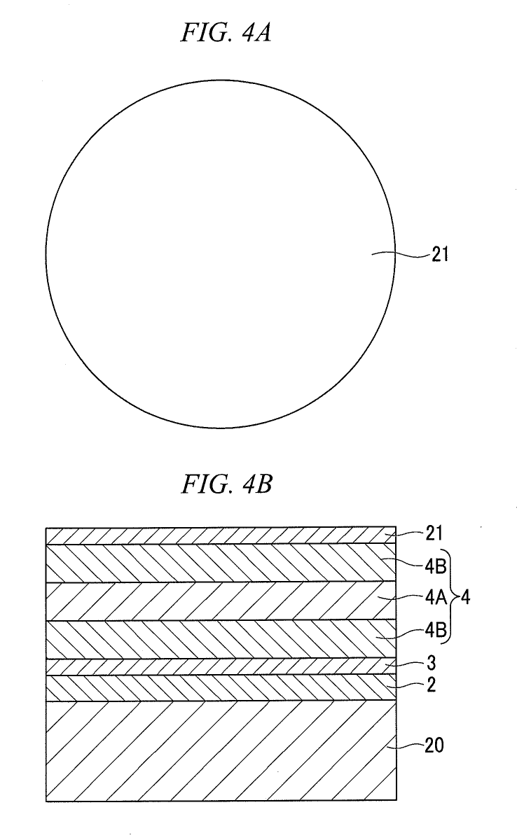

As shown in FIG. 4, in the light-emitting diode of this Comparative Example, the metal protective layer 5 was not formed on the metal substrate 6, dissimilar to Example.

Specifically, the surface opposite to the junction layer 3 of the metal plate 4 was protected with a photo-resist protective film 21 without plating the metal substrate 6 (that is, without forming the metal protective film 5), and then the GaAs substrate was removed. The photo-resist protective film 21 was formed by spin-coating at 2,000 rpm such that the thickness was 2 and then subjected to a heat treatment at 140° C.

[Junction Percentage]

After dissolving and removing the GaAs substrate 20, the junction percentage was measured. As a result, the area of 79% relative to the theoretical area (S) was good. Compared with the result in Example, the junction percentage was lower. This deterioration was caused by dissolution of a part of the periphery of the metal substrate, and the wafer had a portion which could not join.

### Industrial Applicability

The metal substrate for a light-emitting diode of the present invention is excellent in chemical resistance.

Since a light-emitting diode including the metal substrate having excellent chemical resistance is excellent in heat dissipation ability, and can emit light with high light intensity, the light-emitting diode can be useful in various display lamps, lighting equipment, etc. The light-emitting diode has industrial applicability in the field of manufacturing and using a light-emitting diode.

In addition, since the method for manufacturing a light-emitting diode can manufacture a light-emitting diode which has excellent heat dissipation ability, and can emit light with high light intensity, the method can be used in manufacturing various display lamps, lighting equipment, etc. The method for manufacturing a light-emitting diode according to the present invention has industrial applicability in the field of manufacturing and using a light-emitting diode.

[Explanation of reference symbol]

| 1 | light-emitting diode | 2 | compound semiconductor layer |
|---|---|---|---|
| 3 | junction layer | 3A | first metal film |
| 3B | second metal film | 4 | metal plate |
| 5 | metal protective film | | |
| 6 | metal substrate for a light-emitting diode | | |
| 7 | light-emitting portion | 8a | first electrode |
| 8b | second electrode | 9 | clad layer |
| 10 | light-emitting layer | 11 | clad layer |
| 12a | buffer layer | 12b | contact layer |
| 13 | GaP layer | 15 | junction structure |
| 20 | semiconductor substrate | | |

1. A metal substrate for a light-emitting diode including a metal substrate, and a compound semiconductor layer having a light-emitting portion, which is joined over the metal substrate via a junction layer,
wherein the metal substrate for a light-emitting diode includes a metal plate and a metal protective film which covers at least an upper surface and a lower surface of the metal plate.

2. The metal substrate for a light-emitting diode according to claim 1, wherein the metal protective layer further covers side surfaces of the metal plate.

3. The metal substrate for a light-emitting diode according to claim 1, wherein the metal plate has a thermal conductivity of 130 W/m·K or more, and a thermal expansion coefficient which is denoted by a thermal expansion coefficient of the light-emitting portion±1.5 ppm/K.

4. The metal substrate for a light-emitting diode according to claim 1, wherein the metal plate includes at least one of a copper thin plate, a molybdenum thin plate, and a tungsten thin plate.

5. The metal substrate for a light-emitting diode according to claim 4, wherein the metal plate has a structure in which a copper plate and molybdenum plate are laminated.

6. The metal substrate for a light-emitting diode according to claim 1, wherein the metal protective film includes at least one of nickel, chromium, platinum, and gold.

7. A light-emitting diode including a metal substrate according to claim 1, and a compound semiconductor layer having a light-emitting portion, which is joined over the metal substrate via a junction layer, wherein the light-emitting portion includes an AlGaInP layer or an AlGaAs layer.

8. A method for manufacturing a light-emitting diode including:
a first step of forming a metal protective layer on the entire surfaces of a metal plate to produce a metal substrate for a light-emitting diode;
a second step of forming a compound semiconductor layer including a light-emitting portion on a semiconductor substrate;
a third step of forming a junction layer on the compound semiconductor layer;
a fourth step of joining the semiconductor substrate, on which the compound semiconductor layer is formed, and the metal substrate via the junction layer; and
a fifth step of removing the semiconductor substrate using an etchant.

9. The method for manufacturing a light-emitting diode according to claim 8, wherein the first step includes a step of forming the metal plate by thermal-compression bonding plural metal thin plates, and a step of forming the metal protective film on the entire surfaces of the metal plate by plating.
